(19) United States
(12) Patent Application Publication
(10) Pub. No.: US 2014/0015622 A1
(43) Pub. Date: Jan. 16, 2014

(54) HEAT DISSIPATING OUTPUT NETWORK

(71) Applicants: Brad Lindseth, Nederland, CO (US); Terrence F. Hock, Arvada, CO (US)

(72) Inventors: Brad Lindseth, Nederland, CO (US); Terrence F. Hock, Arvada, CO (US)

(73) Assignee: University Corporation for Atmospheric Research, Boulder, CO (US)

(21) Appl. No.: 13/602,969

(22) Filed: Sep. 4, 2012

Related U.S. Application Data
(60) Provisional application No. 61/669,756, filed on Jul. 10, 2012.

(51) Int. Cl. H03H 7/38

(52) U.S. Cl. 333/32

(57) ABSTRACT

A heat dissipating output network (110) is provided. The heat dissipating output network (110) includes one or more impedance elements (204) and one or more capacitors (206), with the one or more impedance elements (204) and the one or more capacitors (206) coupled together in a network configuration, and with the one or more capacitors (206) selected to perform reactance matching and selected to perform a predetermined amount of heat dissipation in the heat dissipating output network (110).

### GOVERNMENT LICENSE RIGHTS

This invention was made with Government support under award number #0856145, proposal #2009-450, awarded by the National Science Foundation. The Government has certain rights in this invention.

### TECHNICAL FIELD

The invention is related to the field of output networks, and more particularly, to output networks for high-power amplifiers.

### BACKGROUND OF THE INVENTION

An amplifier may be used to generate a high-powered signal to be transmitted using an antenna or other emitter device. The high powered amplifier may be constructed to generate a continuous signal power output or may be constructed to generate a pulsed or other non-continuous power output.

An amplifier may require a matching network that matches impedances and reactances to an output device that receives the signal generated and/or amplified by the amplifier. Good matching of impedances and reactances will improve the efficiency of the signal transmission and will minimize signal losses before the signal reaches the output device.

A drawback in a prior art matching network is that the matching network may experience significant heating if the amplifier outputs significant electrical power. The heating may result in damage to components of the matching network, and may even result in damage to other components of the system.

### SUMMARY OF THE INVENTION

In some aspects of the invention, a heat dissipating output network comprises:
one or more impedance elements; and
one or more capacitors, with the one or more impedance elements and the one or more capacitors coupled together in a network configuration, and with the one or more capacitors selected to perform reactance matching and selected to perform a predetermined amount of heat dissipation in the heat dissipating output network.

In some aspects of the invention, a heat dissipating output network comprises:
one or more impedance elements; and
one or more capacitors, with the one or more impedance elements and the one or more capacitors coupled together in a network configuration, and with the one or more capacitors selected to perform reactance matching and selected to perform a predetermined amount of heat dissipation in the heat dissipating output network, wherein the one or more capacitors are selected to meet or exceed a minimum number N of capacitors needed for heat dissipation in the heat dissipating output network.

In some aspects of the invention, a method for providing a heat dissipating output network comprises:
providing one or more impedance elements coupled between a network input and a network output of the heat dissipating output network; and
providing one or more capacitors coupled between the network input and the network output, with the one or more impedance elements and the one or more capacitors configured in a network configuration and with the one or more capacitors selected to perform reactance matching and selected to perform a predetermined amount of heat dissipation in the heat dissipating output network.

### BRIEF DESCRIPTION OF THE DRAWINGS

The same reference number represents the same element on all drawings. It should be understood that the drawings are not necessarily to scale.

FIG. 1 shows a transmitter device according to the invention.

FIG. 2 shows a heat dissipating output network of the transmitter device according to an embodiment of the invention.

FIG. 3 shows the heat dissipating output network according to another embodiment of the invention.

FIG. 4 shows a flowchart of a method for providing a heat dissipating output network according to an embodiment of the invention.

FIG. 5 shows a heat dissipating output network embodiment where two heat dissipation capacitors C₁ and C₂ are employed, such as where the circuit arbitrarily uses two capacitors for output matching or balancing.

FIG. 6 shows a heat dissipating output network embodiment where four heat dissipation capacitors C₁-C₄ are employed, using the capacitor selection method discussed herein.

### DETAILED DESCRIPTION OF THE INVENTION

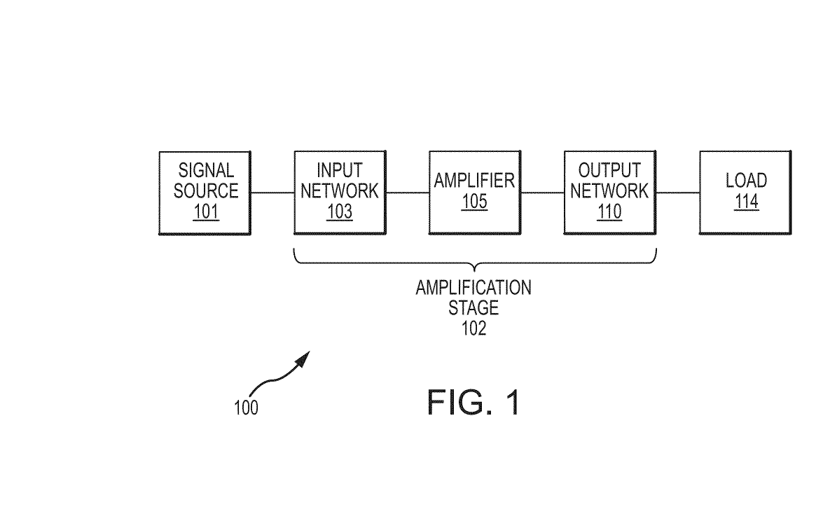

FIGS. 1-6 and the following description depict specific examples to teach those skilled in the art how to make and use the best mode of the invention. For the purpose of teaching inventive principles, some conventional aspects have been simplified or omitted. Those skilled in the art will appreciate variations from these examples that fall within the scope of the invention. Those skilled in the art will appreciate that the features described below can be combined in various ways to form multiple variations of the invention. As a result, the invention is not limited to the specific examples described below, but only by the claims and their equivalents.

FIG. 1 shows a transmitter device 100 according to the invention. The transmitter device 100 comprises a signal source 102, an amplifier 105 coupled to the signal source 102, a heat dissipating output network 110 coupled to the amplifier 105, an output link 114 coupled to the heat dissipating output network 110, and a signal emitting device 115, such as an antenna 115, coupled to the output link 114. The output link 114 may include additional components, such as baluns that perform further output matching.

The signal source 102 generates a signal to be transmitted by the transmitter device 100. The signal source 102 may be a single component or system, as shown, or may comprise multiple components or systems. The signal source 102 may receive one or more external commands, signals, or signal components to use in generating the signal to be transmitted. The signal source 102 may be in communication with external devices, including computers, feedback devices, signal generators, et cetera. The signal outputted by the signal source 102 may be at any suitable power level. The signal may have any suitable waveform characteristics, including a predetermined frequency, a predetermined amplitude, a predetermined modulation, and/or a predetermined power level. The signal in some embodiments may comprise a radar signal, including a wind profiler radar signal.

The amplifier 105 receives the signal outputted by the signal source 102 and amplifies the signal for transmission, generating an output signal. The output signal may comprise a high power output signal. The amplifier 105 may comprise a single amplifier element or may comprise multiple amplifier elements in any desired configuration. The amplifier 105 may amplify the signal by a large amount in some embodiments. For example, the amplifier 105 may receive the signal at a few watts (or even milliwatts) and amplify the signal up to hundreds or even thousands of watts. Such a power time-varying signal will contain significant electrical power. Such a powerful signal will cause components of the transmitter device 100 to radiate significant amounts of heat.

The heat dissipating output network 110 receives the amplified signal and transfers the amplified signal into the antenna link 114. In addition, the heat dissipating output network 110 matches the amplifier 105 and the amplified signal to the antenna link 114 (discussed below).

The antenna link 114 receives the amplified signal from the heat dissipating output network 110. The antenna link 114 transfers the amplified signal to the antenna 115, where it is radiated by the antenna 115.

The heat dissipating output network 110 may perform impedance matching, wherein the impedance of the heat dissipating output network 110 is identical or substantially similar to the impedance of the antenna link 114. In this manner, the power transfer from the amplifier 105 to the antenna 115 is maximized.

To transfer a maximum power, the input impedance of the heat dissipating output network 110 should be equal to or substantially equal to the output impedance of the amplifier 105, while the input reactance of the heat dissipating output network 110 should be substantially equal and opposite of the output reactance of the amplifier 105.

It should be understood that where the amplified signal from the amplifier 105 is at a relatively high power, the heat dissipating output network 110 may radiate a significant amount of heat. This may pose a problem for the heat dissipating output network 110. The heat dissipating output network 110 is at danger of being damaged or destroyed if it is not designed for (and is not capable of) dissipating the heat.

The heat dissipating output network 110 according to any embodiment of the invention is designed to not only match the impedance and reactance of the amplifier 105, but is also designed to provide beneficial and optimal heat dissipation.

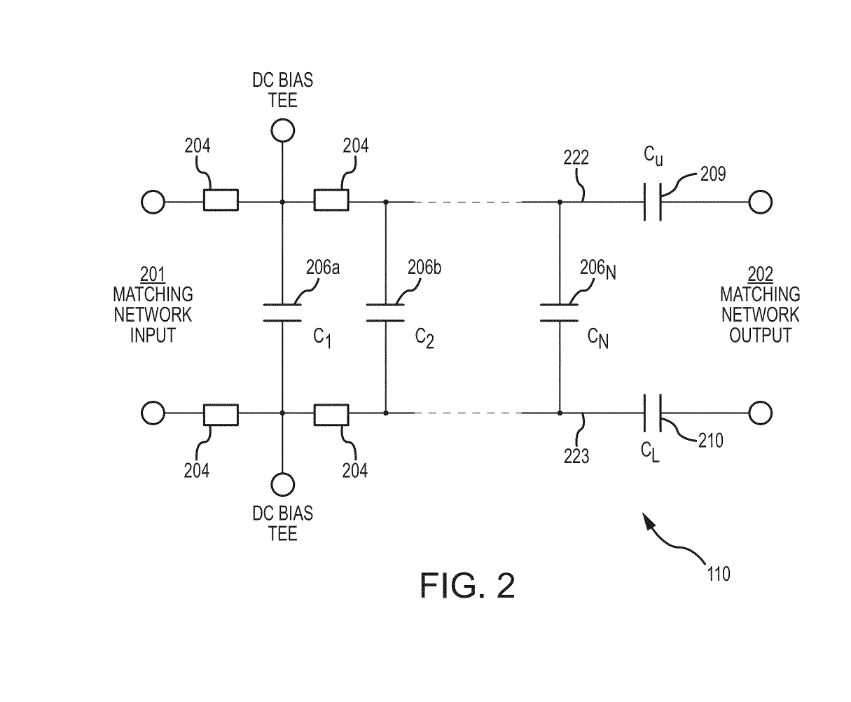

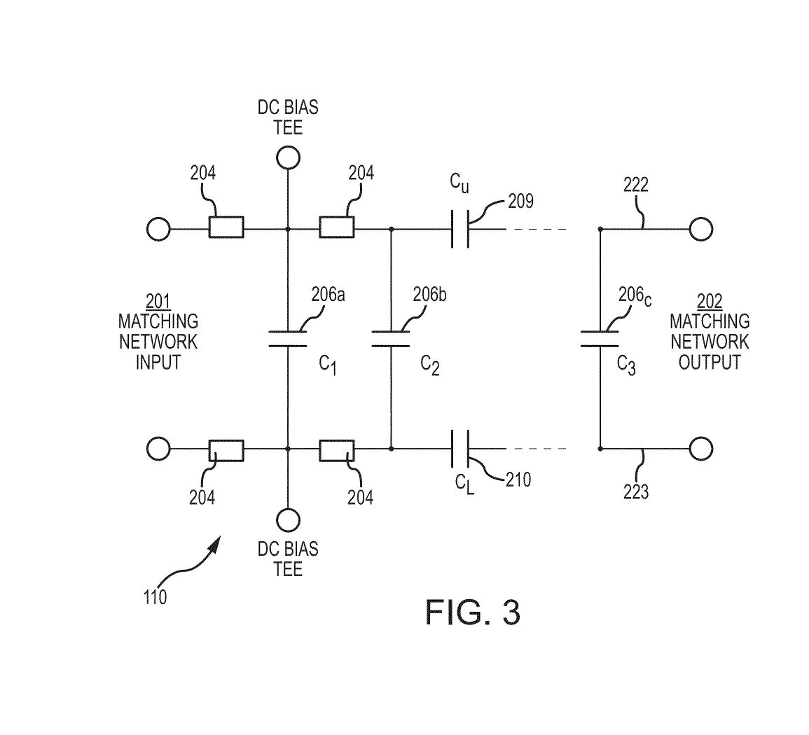

The heat dissipating output network 110 may use one or more capacitors for performing output balancing/matching (see FIGS. 2-3). The one or more capacitors 206 may be chosen not only to provide a proper balancing, but may also be selected to provide optimal heat dissipation.

FIG. 2 shows the heat dissipating output network 110 of the transmitter device 100 according to an embodiment of the invention. The heat dissipating output network 110 may include one or more resistors 204 as impedance elements (I). The one or more resistors 204 are connected in series in an upper network line 222 and in a lower network line 223. The one or more resistors 204 may dissipate some heat and may be formed of appropriate materials. The one or more resistors 204 may comprise or represent characteristic impedances of the upper and lower network lines 222 and 223. Alternatively, the one or more resistors 204 may be in addition to the impedances of the network lines 222 and 223.

The heat dissipating output network 110 may include an upper coupling capacitor C_{U} 209 in the upper network line and a lower coupling capacitor C_{L} 210 in the lower network line. The upper coupling capacitor C_{U} 209 and the lower coupling capacitor C_{L} 210 transfer a signal from the network input 201 to the network output 202. The upper coupling capacitor C_{U} 209 and the lower coupling capacitor C_{L} 210 may isolate the network output 202 from the network input 201. The upper coupling capacitor C_{U} 209 and the lower coupling capacitor C_{L} 210 may block direct current (DC) in the upper network line 222 and in the lower network line 223.

The heat dissipating output network 110 may additionally include one or more capacitors (C₁-C_{N}) 206. The one or more capacitors (C₁-C_{N}) 206 are shown connected in parallel across the upper network line 222 and the lower network line 223. The one or more capacitors (C₁-C_{N}) 206 may be selected to achieve a predetermined reactance in the heat dissipating output network 110 in order to perform reactance matching. In addition, the one or more capacitors (C₁-C_{N}) 206 may be selected to achieve a predetermined amount of heat dissipation in the heat dissipating output network 110. In some embodiments, the one or more capacitors (C₁-C_{N}) 206 may be selected to meet or exceed a minimum number N of capacitors needed for heat dissipation in the heat dissipating output network 110. A greater number of smaller capacitors may offer a greater heat dissipation capacity, as a plurality of physically smaller capacitors may provide a greater total external surface area with respect to their capacitance and therefore may provide a greater heat dissipation capacity than a single capacitor of the same capacitance value.

The one or more capacitors (C₁-C_{N}) 206 may be selected to be capacitors of an optimal type. The one or more capacitors (C₁-C_{N}) 206 may be selected to have an optimal temperature rating. The one or more capacitors (C₁-C_{N}) 206 may be selected to have an optimal heat dissipation capacity. The one or more capacitors (C₁-C_{N}) 206 may be selected to have a maximal surface area.

In some embodiments, the one or more capacitors (C₁-C_{N}) 206 comprise ceramic capacitors. Ceramic capacitors optimally dissipate heat into the environment, such as into the ambient air. In addition, ceramic capacitors can tolerate a high level of heat without degradation or damage to the capacitor.

The one or more resistors 204 and the one or more capacitors (C₁-C_{N}) 206 may be coupled together in a ladder network configuration, as shown. Alternatively, the one or more resistors 204 and the one or more capacitors (C₁-C_{N}) 206 may be coupled together in other network configurations.

A minimum number N of heat dissipation capacitors may be determined. The minimum number N of capacitors may comprise the number of heat dissipation capacitors required in order to operate within acceptable temperature parameters. The minimum number N of capacitors can take into account a known power output that is to be received by and transmitted through the heat dissipating output network 110. It is assumed that the output power comprises a Continuous Wave (CW) power, in watts (W). The output power can be converted from a pulsed or non-continuous power in some embodiments.

The minimum number N of capacitors to be used may be expressed as:

N=1+(CW/PDF) (1)

The CW term comprises the output power in watts to be received in the heat dissipating output network 110. The PDF term comprises a Power Dissipation Factor (PDF) in watts that is related to the power capable of being dissipated by the selected capacitor or capacitors of the heat dissipating output network 110.

According to equation (1), the heat dissipating output network 110 will include at least one heat dissipation capacitor 206. The included integer term “1” is assumed to be a first (and mandatory) capacitor across the network output 202. For example, in some scenarios the (CW/PDF) term may generate a low decimal value that may be rounded down to zero, leaving N=1+0=1. This may result if the output power CW is not significantly larger than the PDF value.

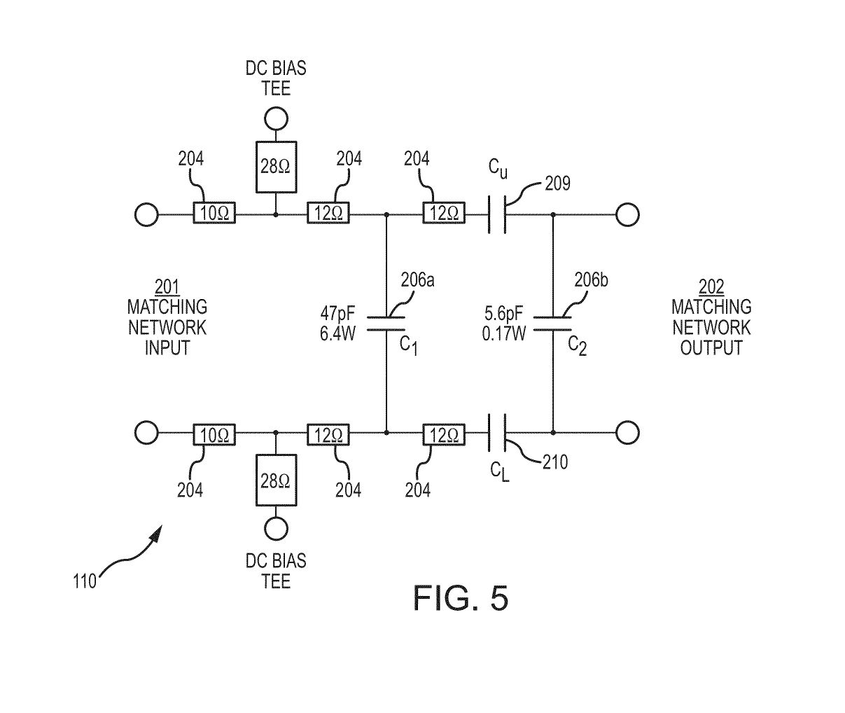

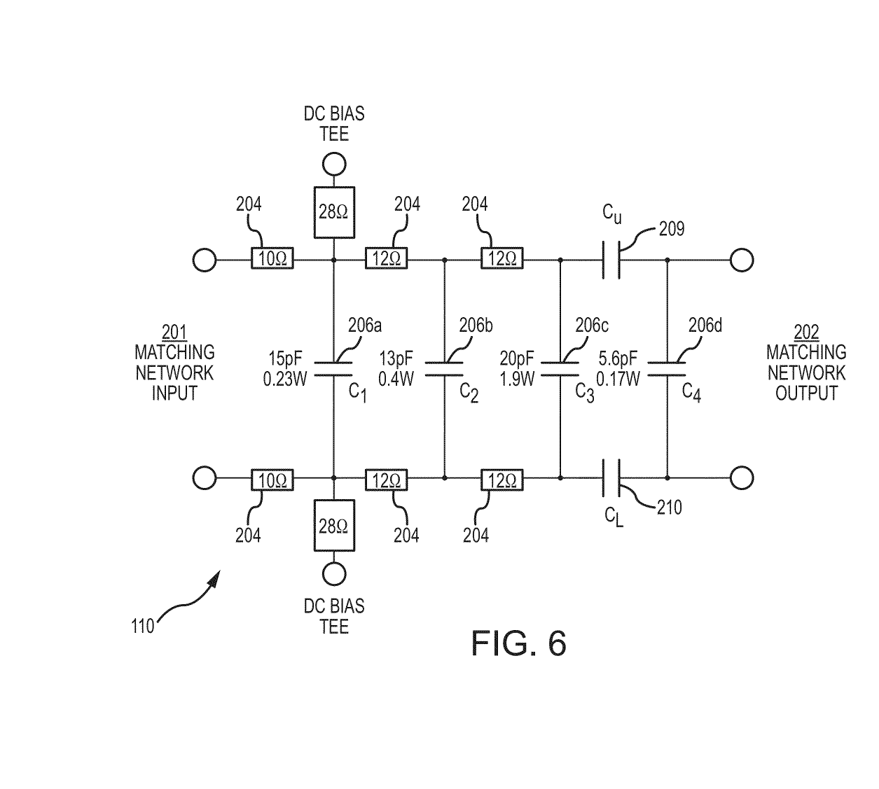

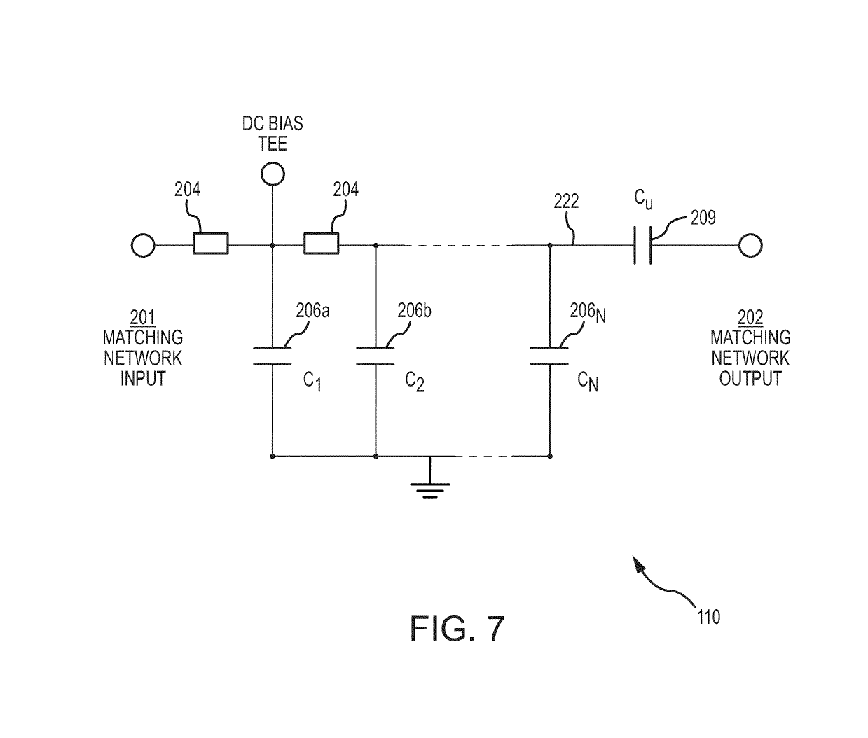

The PDF reflects a basic heat dissipation characteristic of a capacitor 206 used in the heat dissipating output network 110. The PDF mainly comprises a capacitor parasitic resistance (see FIGS. 5-6 and the accompanying text). The capacitor parasitic resistance (or impedance) comprises a resistance exhibited by a non-ideal capacitor, and will result in some heating within the capacitor when power flows through the heat dissipating output network 110.

The capacitor parasitic resistance can be obtained from various sources. In one embodiment, the capacitor parasitic resistance can comprise information published by the manufacturer. In another embodiment, the capacitor parasitic resistance can be experimentally derived or measured, for example.

Other capacitor characteristics and/or operational characteristics can be included in the PDF, if desired. For example, the PDF may take into account some or all of a capacitor type, a capacitance value of a selected capacitor to be used, a temperature rating of the selected capacitor, expected ambient conditions, including, for example, expected ambient temperature and/or humidity and the effect of any cooling mechanisms, characteristics of the output power, such as expected variations over time, and a safety or temperature threshold designed to keep operating temperature of the capacitors away from critical heating values. The above listing is not exhaustive, and other PDF variables are contemplated and are within the scope of the description and claims. Further, the PDF term may include a constant or constants, including empirically or experimentally derived terms. Therefore, by selecting an appropriate capacitor or capacitors, the minimum number N of heat dissipation capacitors (C₁-C_{N}) 206 may be determined.

For example, for an actual power output of 1.25 kW pulsed, the CW output power may comprise about 125 W. The PF may be, for example, a value of 41.6 for a ceramic capacitor operating within standard temperature conditions. A desire maximum temperature of 100 to 125 degrees Centigrade may be assumed as a temperature limitation. The resulting number N of capacitors is: N=1+(125/41.6)=1+3=4. Therefore, in this example, a minimum of four such capacitors (N=4) would be needed as heat dissipating capacitors in the heat dissipating output network 110. It should be understood that more than four capacitors could be employed, if desired. Fewer capacitors than this number may result in the amplifier output matching capacitors heating up above a rated operating temperature.

FIG. 3 shows the heat dissipating output network 110 according to another embodiment of the invention. In this embodiment, the third and final heat dissipation capacitor C₃ 206c is located to the right of the upper coupling capacitor C_{U} 209 and the lower coupling capacitor C_{L} 210. The final heat dissipation capacitor C₃ 206 will still dissipate a portion of the heat of the heat dissipating output network 110. It should be understood that the upper coupling capacitor C_{U} 209 and the lower coupling capacitor C_{L} 210 may be located in any sequence or organization with respect to the one or more capacitors (C₁-C_{N}) 206.

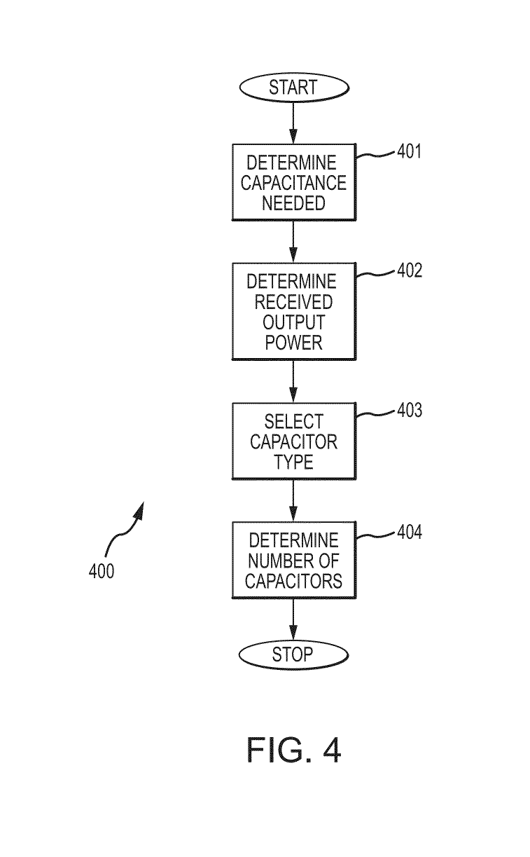

FIG. 4 shows a flowchart of a method for providing a heat dissipating output network according to an embodiment of the invention. In step 401, a total capacitance value for the heat dissipating output network 110 is determined The capacitance may be determined in any suitable manner.

In step 402, the output power to be received is determined. The output power may comprise a continuous wave (CW) output power, although a non-continuous or pulsed power may be used in the number computation, if desired. Alternatively, the output power may be converted into a CW value.

In step 403, a capacitor type may be selected. The capacitor type may comprise any available or suitable capacitor type. For example, a heat tolerant capacitor type may be preferred, such as a ceramic capacitor. In addition, the capacitor cost may also be taken into account. Further, the capacitor type may be chosen according to known thermal characteristics.

In step 404, a minimum number N of capacitors for the heat dissipating output network 110 is determined. The determined number of capacitors may comprise a minimum number N of capacitors that will meet or exceed a predetermined heat dissipation capacity.

The minimum number N of capacitors may be determined according to the equation N=1+(CW/PF), as previously discussed, where PDF is the predetermined Power Dissipation Factor and CW is the Continuous Wave power output to be received by the heat dissipating output network. Therefore, by selecting an appropriate capacitor or capacitors, the minimum number N of heat dissipation capacitors may be determined.

The determined number N of capacitors may be used to construct the heat dissipating output network 110. Alternatively, a greater than determined number of capacitors may be used in order to construct the heat dissipating output network 110 with a greater than required heat dissipation capacity, i.e., to create a margin of error and obtain a greater robustness.

The determined number N of capacitors may need to take into account both the total capacitance needed and the needed heat dissipation capacity. It should be noted that the selected capacitors do not need to all be of the same capacitor type. It should be noted that the selected capacitors do not need to all be of the same capacitance size.

The determined number N of capacitors for the heat dissipating output network 110 may depend on the type of selected capacitors. The determined number N of capacitors may depend on the total capacitance value to be achieved. The determined number N of capacitors may depend on the available sizes of the selected capacitor type. The determined number N of capacitors may comprise capacitors of a physical size that will add up to a heat dissipation capability that meets or exceeds a predetermined heat dissipation capacity. The determined number N of capacitors may depend on the heat dissipation characteristics of the selected capacitor type (which may depend on the relative size and material of the selected capacitor type).

FIG. 5 shows a heat dissipating output network embodiment where two heat dissipation capacitors C₁ and C₂ are employed, such as where the circuit arbitrarily uses two capacitors for output matching or balancing. However, as is shown below, the two capacitors are inadequate in terms of heat dissipation.

In this example, the capacitor C₁ has a value of 47 picofarad (pF) and exhibits a capacitor parasitic resistance of 0.05 ohm The capacitor C₂ has a value of 5.6 pF and exhibits a capacitor parasitic resistance of 0.1 ohm The electrical current through C₁ will be about 11.3 amp (A) and the power dissipation in C₁ will be about 6.4 W. The current through C₂ will be about 1.3 A and the power dissipation in C₂ will be about 0.17 W.

It can be seen that the capacitor C₁ dissipates most of the heat. From just this aspect alone, where C₁ dissipates most of the power and C₂ dissipates very little power, it can be seen that this heat dissipating output network embodiment is not satisfactory.

In this example, where N=2, the capacitor C₃ dissipates the most power at 6.4 W. However, the 6.4 W power dissipation in the capacitor C₁ will lead to an unacceptable capacitor temperature. A power dissipation in a capacitor of 3 W will result in a case temperature of about 125 degrees Centigrade (assuming steady state power through the capacitor). In some embodiments, this may be considered to be a safe upper limit for a ceramic or equivalent capacitor. Accordingly, the figure shows a heat dissipating output network embodiment where the heat dissipation is insufficient and where overheating damage may occur as a result.

FIG. 6 shows a heat dissipating output network embodiment where four heat dissipation capacitors C₁-C₄ are employed, using the capacitor selection method discussed herein. In this embodiment, the circuit has been designed using equation (1) to find the minimum number N of capacitors 206 to be used, where: N=1+(CW/PDF) or N=1+(125/41.6)=1.3.00=4. As before, this example uses a CW value of 125 W and a PDF value of 41.6 W.

In this example, the capacitor C₁ has a value of 15 pF and exhibits a parasitic resistance of 0.07 ohm, the capacitor C₂ has a value of 13 pF and exhibits a parasitic resistance of 0.075 ohm, the capacitor C₃ has a value of 20 pF and exhibits a parasitic resistance of 0.065 ohm, and the capacitor C₄ has a value of 5.6 pF and exhibits a parasitic resistance of 0.1 ohm. The electrical current through C₁ will be about 1.8 A and the power dissipation in C₁ will be about 0.23 W. The current through C₂ will be about 2.3 A and the power dissipation in C₂ will be about 0.4 W. The current through C₃ will be about 5.4 A and the power dissipation in C₃ will be about 1.9 W. The current through C₄ will be about 1.3 A and the power dissipation in C₄ will be about 0.17 W.

In this example, the power dissipated in any capacitor of the three capacitor embodiment (i.e., for N=4) will not exceed about 1.9 W. As discussed above, a power dissipation of 3 W in a capacitor should not generate an operational capacitor temperature that exceeds 125 degrees Centigrade. Further, it should be noted that the power dissipation is more evenly distributed between the capacitors than the embodiment shown in FIG. 5.

The various embodiments of the invention can be implemented to provide several advantages, if desired. The heat dissipating output network may provide a matching network for balancing the output of an amplifier, including a high-power amplifier. The amplifier may generate a significant amount of heat in the output. The output balancing network must dissipate heat without becoming damaged, in addition to performing an output balancing or matching function. The present invention comprises an output balancing network wherein the number and type of capacitors are specifically chosen for reactance matching and for heat dissipation. The number of capacitors may be chosen to perform a predetermined amount of heat dissipation. The number of capacitors may be chosen to perform a predetermined amount of heat dissipation and may provide a heat dissipation capability that provides a tolerance wherein unexpected power transmission conditions or environmental conditions cannot cause overheating or damage.

The detailed descriptions of the above embodiments are not exhaustive descriptions of all embodiments contemplated by the inventors to be within the scope of the invention. Indeed, persons skilled in the art will recognize that certain elements of the above-described embodiments may variously be combined or eliminated to create further embodiments, and such further embodiments fall within the scope and teachings of the invention. It will also be apparent to those of ordinary skill in the art that the above-described embodiments may be combined in whole or in part to create additional embodiments within the scope and teachings of the invention.

Thus, although specific embodiments of, and examples for, the invention are described herein for illustrative purposes, various equivalent modifications are possible within the scope of the invention, as those skilled in the relevant art will recognize. The teachings provided herein can be applied to other electrical networks, and not just to the embodiments described above and shown in the accompanying figures. Accordingly, the scope of the invention should be determined from the following claims.

We claim:

1. A heat dissipating output network (110), comprising:
one or more impedance elements (204); and
one or more capacitors (206), with the one or more impedance elements (204) and the one or more capacitors (206) coupled together in a network configuration, and with the one or more capacitors (206) selected to perform reactance matching and selected to perform a predetermined amount of heat dissipation in the heat dissipating output network (110).

2. The heat dissipating output network (110) of claim 1, wherein the one or more capacitors (206) are selected to meet or exceed a minimum number N of capacitors needed for heat dissipation in the heat dissipating output network (110).

3. The heat dissipating output network (110) of claim 1, wherein a capacitor (206) of the one or more capacitors (206) is chosen to have an optimal temperature rating.

4. The heat dissipating output network (110) of claim 1, wherein a capacitor (206) of the one or more capacitors (206) is chosen to have an optimal heat dissipation capacity.

5. The heat dissipating output network (110) of claim 1, wherein a capacitor (206) of the one or more capacitors (206) is chosen to have a maximal surface area.

6. The heat dissipating output network (110) of claim 1, with a network input (201) of the heat dissipating output network (110) adapted to be coupled to an amplifier (105) and with a network output (202) adapted to be coupled to a signal emitting device (115).

7. The heat dissipating output network (110) of claim 1, with the heat dissipating 1 output network (110) further comprising:
an upper network line (222) extending between a network input (201) and a network output (202) of the heat dissipating output network (110);
an upper coupling capacitor C_{U} (209) connected in series in the upper network line (222) and configured to block direct current (DC);
a lower network line (223) extending between the network input (201) and the network output (202); and
a lower coupling capacitor C_{L} (210) connected in series in the lower network line (223) and configured to block DC.

8. The heat dissipating output network (110) of claim 1, with the heat dissipating output network (110) further comprising:
an upper network line (222) extending between a network input (201) and a network output (202) of the heat dissipating output network (110);
an upper coupling capacitor C_{U} (209) connected in series in the upper network line (222) and configured to block direct current (DC);
a lower network line (223) extending between the network input (201) and the network output (202);
a lower coupling capacitor C_{L} (210) connected in series in the lower network line (223) and configured to block DC;
the one or more impedance elements (204) connected in series in one or both of the upper network line (222) and the lower network line (223); and
the one or more capacitors (206) connected in parallel across the upper network line (222) and the lower network line (223).

9. A heat dissipating output network (110), comprising:
one or more impedance elements (204); and
one or more capacitors (206), with the one or more impedance elements (204) and the one or more capacitors (206) coupled together in a network configuration, and with the one or more capacitors (206) selected to perform reactance matching and selected to perform a predetermined amount of heat dissipation in the heat dissipating output network (110), wherein the one or more capacitors (206) are selected to meet or exceed a minimum number N of capacitors needed for heat dissipation in the heat dissipating output network (110).

10. A method for providing a heat dissipating output network, comprising:
providing one or more impedance elements coupled between a network input and a network output of the heat dissipating output network; and
providing one or more capacitors coupled between the network input and the network output, with the one or more impedance elements and the one or more capacitors configured in a network configuration and with the one or more capacitors selected to perform reactance matching and selected to perform a predetermined amount of heat dissipation in the heat dissipating output network.

11. The method of claim 10, with selecting the one or more capacitors further comprising selecting the one or more capacitors to meet or exceed a minimum number N of capacitors needed for heat dissipation in the heat dissipating output network.

12. The method of claim 10, further comprising selecting a capacitor of the one or more capacitors for an optimal temperature rating.

13. The method of claim 10, further comprising selecting a capacitor of the one or more capacitors for an optimal heat dissipation capacity.

14. The method of claim 10, further comprising selecting a capacitor of the one or more capacitors for a maximal surface area.

15. The method of claim 10, further comprising:
providing an upper network line;
providing an upper coupling capacitor C_{U} connected in the upper network line and configured to block direct current (DC);
providing a lower network line; and
providing a lower coupling capacitor C_{L} connected in the lower network line and configured to block DC.

16. The method of claim 10, further comprising:
providing an upper network line;
providing an upper coupling capacitor C_{U} connected in the upper network line and configured to block direct current (DC);
providing a lower network line;
providing a lower coupling capacitor C_{L} connected in the lower network line and configured to block DC;
connecting the one or more impedance elements in series in one or both of the upper network line and the lower network line; and
connecting the one or more capacitors in parallel across the upper network line and the lower network line.
